(19) United States
(12) Patent Application Publication
(10) Pub. No.: US 2008/0305644 A1
(43) Pub. Date: Dec. 11, 2008

(54) Method of manufacturing semiconductor device including trench-forming process

(75) Inventors: Yoshitaka Noda, Ichinomiya-city (JP); Tsuyoshi Yamamoto, Kariya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/153,634

(22) Filed: May 22, 2008

(30) Foreign Application Priority Data
Jun. 7, 2007 (JP) 2007-152075

(51) Int. Cl. H01L 21/306

(52) U.S. Cl. 438/733; 257/E21.215

(57) ABSTRACT

In a manufacturing method of a semiconductor device, a trench is formed in a semiconductor substrate by an anisotropic dry etching so as to have an aspect ratio greater than or equal to 10, and a damaged layer that is generated in a wall and a bottom of the trench due to the anisotropic dry etching is removed by an isotropic dry etching. The isotropic dry etching is performed with a first gas including carbon and fluorine and a second gas including oxygen. A temperature of the semiconductor substrate is controlled so that the damaged layer is removed from a whole surface of the wall and the bottom in the isotropic dry etching.

### CROSS REFERENCE TO RELATED APPLICATION

The present application is based on and claims priority to Japanese Patent Application No. 2007-152075 filed on Jun. 7, 2007, the contents of which are incorporated in their entirety herein by reference.

### BACKGROUND OF THE INVENTION

1. Field of the Invention

The present invention relates to a method of manufacturing a semiconductor device including a trench-forming process.

2. Description of the Related Art

Conventionally, a trench is formed in a semiconductor substrate by an anisotropic dry etching for manufacturing a semiconductor device that includes a trench for isolating elements, a gate electrode having a trench structure such as a metal-oxide semiconductor element (MOS element) and an isolated gate bipolar transistor (IGBT), or a super junction element having a pn structure in which n-type regions and p-type regions are alternately arranged. In the anisotropic dry etching, accelerated ions are collided with the semiconductor substrate, and thereby the semiconductor substrate is etched. Thus, a damaged layer is generated in a wall and a bottom of the trench. When the semiconductor substrate is subjected to a heat treatment in a state where the damaged layer remains, a crystal defect may be generated or an insulation film may be difficult to be formed on the wall and the bottom of the trench with a high degree of accuracy.

U.S. Pat. No. 6,448,139 (corresponding to JP-2001-351895A) discloses a method of removing the damaged layer. In the method, after forming the trench by an anisotropic dry etching, the damage layer is removed by an isotropic wet etching using a liquid mixture of hydrofluoric acid and nitric acid. When a trench having a high aspect ratio greater than or equal to 10 is formed, the liquid mixture is difficult to be supplied to a bottom portion of the trench due to a surface tension. Thus, the damaged layer may remain at a portion of the wall and the bottom of the trench.

Alternatively, an isotropic dry etching may be used for forming the trench. However, when a trench having a high aspect ratio greater than or equal to 10 is formed by a conventional isotropic dry etching, etchant gas is difficult to be supplied to the bottom portion of the trench. Thus, an opening portion of the trench is selectively etched, and thereby the trench has a funnel shape having a step portion on the wall. In the present case, an electric field concentration may occur at the step portion. In addition, at the step portion and the bottom portion at which the damaged layer remains, a crystal defect may be generated or the insulation film may be difficult to be formed with a high degree of accuracy.

Alternatively, a bias may be applied to the semiconductor substrate so as to etch the bottom portion of the trench having a high aspect ratio. In the present case, ions are introduced to the bottom portion of the trench. However, the accelerated ions may generate additional damaged layer in the semiconductor substrate.

JP-2003-7676A discloses a method of etching a bottom portion of a trench by an isotropic dry etching. In the method, after the trench is formed in the semiconductor substrate by an anisotropic dry etching, a silicon nitride layer is formed on the whole surface of a wall and a bottom of the trench. The silicon nitride layer at the bottom portion of the trench is removed by an anisotropic etching. Then, an isotropic etching is performed so that the bottom portion of the trench is rounded and the damaged layer generated in the semiconductor substrate is removed.

In the present method, only the bottom portion of the wall of the trench, which is exposed to an outside of the silicon nitride layer, is isotropically etched. Thus, a step portion may be generated at a boundary between a portion covered by the silicon nitride layer and a portion exposed to an outside of the silicon nitride layer. Thereby, the trench may have a shape similar to a measuring flask. As a result, an electric field concentration may occur at the step portion. Furthermore, at the step portion and a portion at which the damaged layer remains due to the silicon nitride layer disposed thereon, a crystal defect may be generated or the insulation layer may be difficult to be formed with a high degree of accuracy.

### SUMMARY OF THE INVENTION

In view of the foregoing problems, it is an object of the present invention to provide a method of manufacturing a semiconductor device.

According to a first aspect of the invention, a method of manufacturing a semiconductor device, includes: forming a trench in a semiconductor substrate by an anisotropic dry etching, in which the trench has an aspect ratio greater than or equal to 10 and the semiconductor substrate includes silicon; and removing a damaged layer that is generated in a wall and a bottom of the trench due to the anisotropic dry etching by an isotropic dry etching. The isotropic dry etching is performed with a first gas including carbon and fluorine and a second gas including oxygen. In the isotropic dry etching, a temperature of the semiconductor substrate is controlled so that the damaged layer is removed from a whole surface of the wall and the bottom.

In the present method, the semiconductor device that includes the trench having a high aspect ratio greater than or equal to 10 can be manufactured and the damaged layer can be removed from the whole surface of the wall and the bottom of the trench.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1 is a cross-sectional view showing an effect of a polymerized film in an isotropic etching;

FIG. 2 is a cross-sectional view showing an effect of removing the polymerized film in the isotropic etching;

FIG. 3 is a graph showing a relationship between a depth of a trench and an etching rate at different temperatures;

FIG. 4 is a graph showing a relationship between an aspect ratio of a trench and an etching rate ratio of a bottom portion to an opening portion at different temperatures;

FIG. 5 is a cross-sectional view showing a trench in a case where an etching rate of the trench is substantially uniform in a depth direction;

FIG. 6 is a cross-sectional view showing a trench in a case where the etching rate increases toward the bottom portion;

FIG. 7 is a cross-sectional view showing a trench in a case where the etching rate increases toward the opening portion;

FIG. 8 is a cross-sectional view showing a masking process in a manufacturing method of a semiconductor device according to a first embodiment of the invention;

FIG. 9 is a cross-sectional view showing a trench-forming process in the manufacturing method according to the first embodiment;

FIG. 10 is a cross-sectional view showing a removing process in the manufacturing method according to the first embodiment;

FIG. 11 is a cross-sectional view showing a trench-forming process in a manufacturing method of a semiconductor device according to a modification of the first embodiment;

FIG. 12 is a cross-sectional view showing a removing process in the manufacturing method according to the modification of the first embodiment;

FIG. 13 is a cross-sectional view showing a trench-forming process in a manufacturing method of a semiconductor device according to a second embodiment of the invention;

FIG. 14 is a cross-sectional view showing a removing process in the manufacturing method according to the second embodiment;

FIG. 15 is a cross-sectional view showing a trench-forming process in a manufacturing method of a semiconductor device according to a modification of the second embodiment;

FIG. 16 is a cross-sectional view showing a removing process in the manufacturing method according to the modification of the second embodiment;

FIG. 17 is a cross-sectional view showing a trench-forming process in a manufacturing method of a semiconductor device according to a third embodiment of the invention;

FIG. 18 is a cross-sectional view showing a removing process in the manufacturing method according to the third embodiment;

FIG. 19 is a cross-sectional view showing a trench-forming process in a manufacturing method of a semiconductor device according to a modification of the third embodiment;

FIG. 20 is a cross-sectional view showing a removing process in the manufacturing method according to the modification of the third embodiment; and

FIG. 21 is a cross-sectional view showing a removing process in a manufacturing method of a semiconductor device according to another modification of the invention.

### DETAILED DESCRIPTION OF THE PREFERRED EMBODIMENTS

A process that the inventors of the present application create the present invention will be described before describing preferred embodiments of the invention.

At first, a trench is formed in a semiconductor substrate including silicon by an anisotropic dry etching. Then, a damaged layer generated in a wall and a bottom of the trench is removed by an isotropic dry etching using a reaction gas including a first gas and a second gas. The first gas includes at least carbon and fluorine and the second gas includes oxygen. For example, the first gas is tetrafluoromethane. A pressure in a chamber is set to be about 30 Pa, and a flow ratio of the first gas to the second gas is set to be about 1.

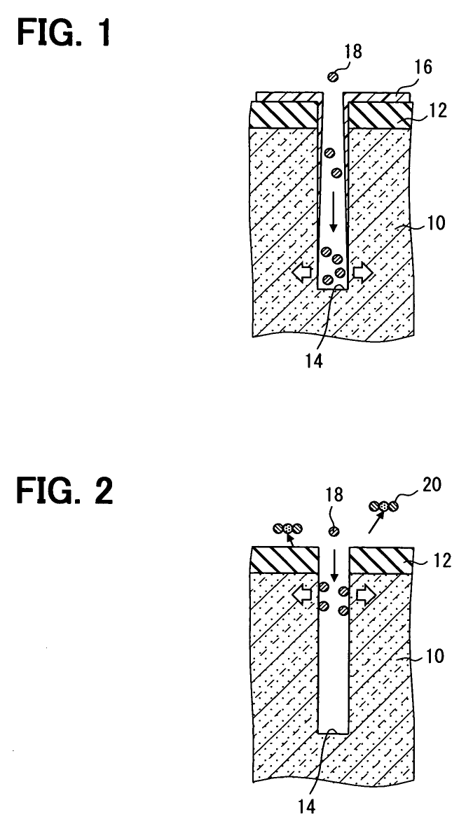

Specifically, as shown in FIG. 1, a mask 12 is formed on a surface of a semiconductor substrate 10 made of silicon. For example, the mask 12 may be made of a silicon dioxide film. The mask 12 has an opening portion 12a corresponding to a trench-forming position. Then, a trench 14 is formed by the anisotropic dry etching through the mask 12. For example, the anisotropic dry etching may be a reactive ion etching (RIE). After forming the trench 14, the damaged layer (not shown) generated in the wall and the bottom of the trench is removed by an isotropic dry etching.

When the first gas is decomposed by a plasma discharge, a polymerized film is formed from carbon and other element in the first gas such as fluorine. As shown in FIG. 1, the polymerized film 16 deposits from an upper side of the mask 12 and a side of an opening portion of the trench 14 that are close to a plasma discharging area. Thus, a thickness of the polymerized film 16 increases toward the opening portion in a depth direction of the trench 14. In addition, fluorine radicals 18 as active species are excited by the plasma discharge. The polymerized film 16 restricts the fluorine radicals 18 from etching the semiconductor substrate 10. Specifically, the polymerized film 16 restricts the fluorine radicals 18 from reacting silicon in the trench wall to form a volatile product that is desorbed from the surface of the wall. Thus, when the polymerized film 16 is provided, the fluorine radicals 18 are supplied to a bottom portion of the trench 14, as shown in FIG. 1, and thereby the bottom portion is isotropically etched.

In addition, oxygen used as the second gas generates oxygen radicals excited by the plasma discharge. The oxygen radicals react with carbon in the polymerized film 16 to form carbon dioxide 20. Because the carbon dioxide 20 is desorbed from the surface of the wall, the polymerized film 16 is removed. Thus, in a state where the polymerized film 16 is wholly removed or the polymerized film 16 is almost removed, the fluorine radicals 18 as active species etch the wall in the vicinity of the opening portion that is close to the plasma discharging area.

Therefore, the formation of the polymerized film 16 and the removal of the polymerized film 16 are important factors for determining an etching rate at each portion of the trench wall. As one of parameters for controlling the formation and the removal of the polymerized film 16, a temperature dependency of the etching rate can be investigated as was demonstrated by the inventors.

At first, the trench 14 having a width about 0.8 μm is treated by an isotropic dry etching while keeping a temperature of the semiconductor substrate 10 at 70° C., 90° C., and 120° C. In addition, etching rates in a case where the isotropic dry etching is performed at 60° C., 80° C., 100° C., 110° C., and 130° C. are simulated.

As shown in FIG. 3, when the temperature of the semiconductor substrate 10 is 90° C., etching rates at the opening portion (trench depth is 0 μm), a middle portion (trench depth is about 10 μm), and the bottom portion (trench dept is about 20 μm) of the trench 14 are substantially equal to each other. When the temperature of the semiconductor substrate 10 is 70° C., the etching rate increases toward the bottom portion although the damaged layer can be removed at each portion in the depth direction. When the temperature of the semiconductor substrate 10 is 120° C., the etching rate decreases toward the bottom portion although the damaged layer can be removed at each portion in the depth direction.

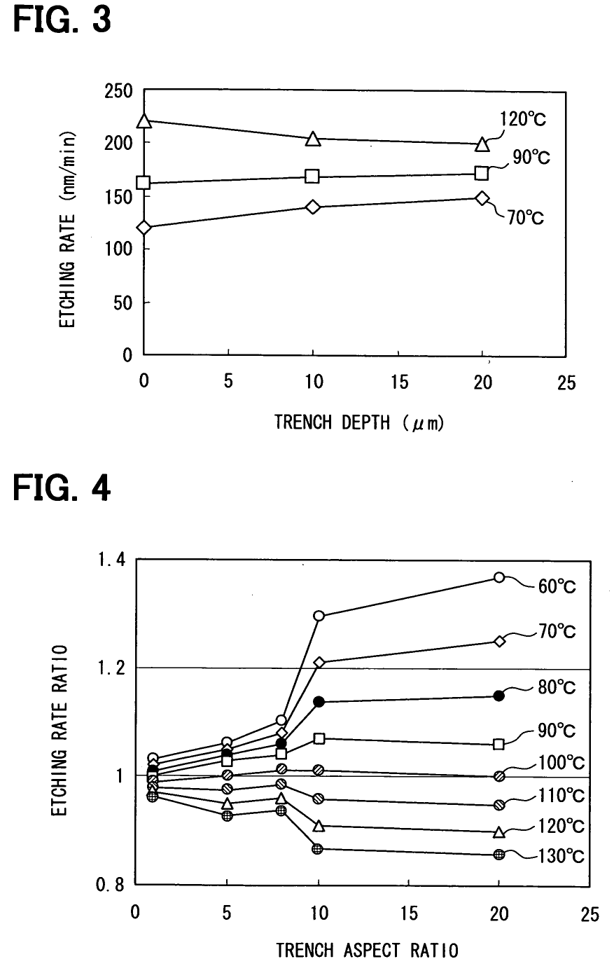

As shown in FIG. 4, when an aspect ratio of the trench 14 is greater than or equal to 10, the etching rate of the trench wall can be effectively controlled by the temperature of the semiconductor substrate 10. In addition, when the temperature of the semiconductor substrate 10 is in a range from 90° C. to 110° C., for example 100° C., a ratio of the etching rate at the bottom portion to the etching rate at the opening portion is about 1. That is, when the temperature of the semiconductor substrate 10 is in a range from 90° C. to 110° C., the etching rate at each portion of the trench 14 are substantially equal to each other. When the temperature of the semiconductor substrate 10 is greater than 110° C., the etching rate at the opening portion is larger than the etching rate at the bottom portion because the etching-restrictive effect at the opening portion by the polymerized film 16 is reduced compared with a case where the temperature of the semiconductor substrate 10 is in a range from 90° C. to 110° C. When the temperature of the semiconductor substrate 10 is less than 90° C., the etching rate at the opening portion is less than the etching rate at the bottom portion because the etching-restrictive effect at the opening portion by the polymerized film 16 increases compared with a case where the temperature of the semiconductor substrate 10 is in a range from 90° C. to 110° C.

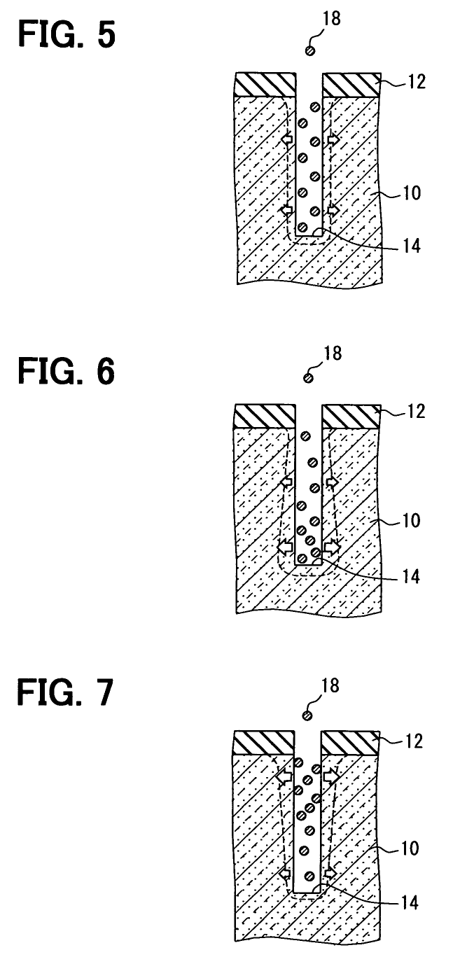

Thus, when the trench 14 having the aspect ratio greater than or equal to 10 is treated by the isotropic dry etching, the etching rate of the wall and the bottom of the trench can be controlled by the temperature of the semiconductor substrate 10. When the fluorine radicals 18 are supplied to each portion of the trench wall uniformly, the etching rate of the trench wall is substantially uniform in the depth direction, and thereby the width of the trench 14 is substantially uniform in the depth direction as shown by the broken line in FIG. 5. When the fluorine radicals 18 are supplied to the bottom portion more than the opening portion, the etching rate at the bottom portion becomes larger than the etching rate at the opening portion, and thereby the width at the bottom portion becomes larger than the width at the opening portion as shown by the broken line in FIG. 6. When the fluorine radicals 18 are supplied to the opening portion more than the bottom portion, the etching rate at the opening portion becomes larger than the etching rate at the bottom portion, and thereby the width at the opening portion becomes larger than the width at the bottom portion as shown by the broken line in FIG. 7. As a result, the etching rate of the trench wall can be controlled by the temperature of the semiconductor substrate 10 so that the etching rate is substantially uniform in the depth direction, the etching rate increases toward the bottom portion, or the etching rate decreases toward the bottom portion. The present invention is created based on the above-described findings.

### First Embodiment

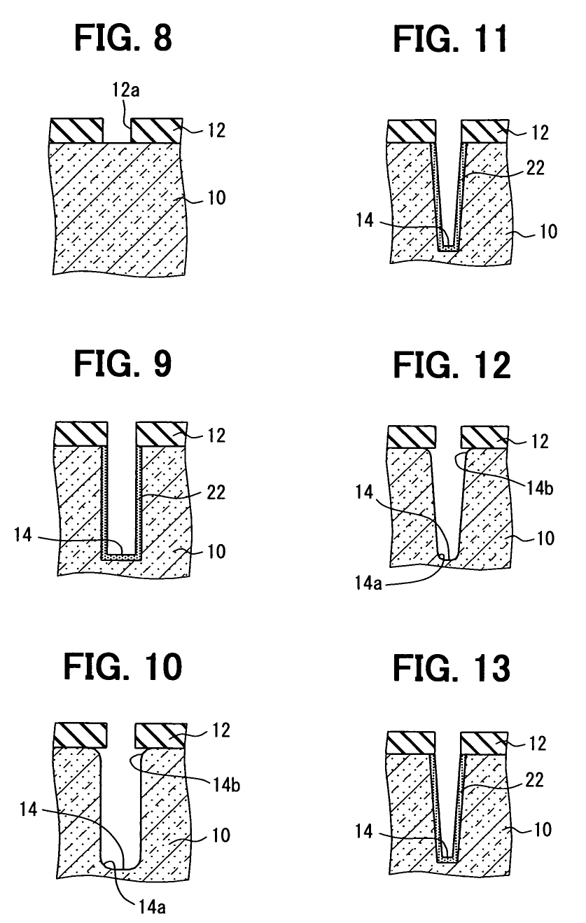

A manufacturing method of a semiconductor device according to a first embodiment of the invention will be described with reference to FIGS. 8-10. At first, the semiconductor substrate 10 made of silicon is prepared. Then, as shown in FIG. 8, the mask 12 is formed on a surface of the semiconductor substrate 10. The mask 12 has the opening portion 12a at a portion corresponding to a position at which the trench 14 is formed. The mask 12 functions as a mask in a trench-forming process by an anisotropic dry etching. In the present embodiment, the mask 12 is made of a silicon dioxide film that is pattern-formed.

Next, the trench 14 is formed by an anisotropic dry etching through the mask 12. As the anisotropic dry etching, an etching in which an effect by a physical etching is larger than an effect by a chemical etching may be used. In the present embodiment, the RIE is used as the anisotropic dry etching. In the anisotropic dry etching, accelerated ions are collided with a portion of the semiconductor substrate 10 that is exposed to an outside through the opening portion 12a of the mask 12. Thereby, the portion is physically etched by the sputter etching, and the damaged layer 22 is generated in the trench wall of the semiconductor substrate 10. The trench 14 has a vertical shape in a direction approximately perpendicular to the surface of the semiconductor substrate 10 and the width of the trench 14 is substantially uniform in the depth direction. For example, the trench 14 has an aspect ratio about 20.

After forming the trench 14, an isotropic dry etching is performed for removing the damaged layer 22. For example, tetrafluoromethane (CF₄) is used as the first gas that includes carbon and fluorine, and oxygen is used as the second gas. The pressure in the chamber is set to be about 30 Pa, and the flow ratio of the first gas to the second gas is set to be about 1. The temperature of the semiconductor substrate 10 is set to be a predetermined temperature in a range from 90° C. to 110° C. When the trench 14 is treated by the isotropic dry etching on the above-described conditions, the etching rate is substantially uniform in the depth direction and the ratio of the etching rate at the bottom portion to the etching rate at the opening portion is about in a range from 0.95 to 1.05, as shown in FIGS. 3-5. Thus, the wall and the bottom of the trench are etched substantially uniformly over the whole surface, and thereby the damaged layer 22 can be removed from the whole surface of the wall and the bottom of the trench, as shown in FIG. 10. As a result, a generation of a crystal defect due to the damaged layer 22 can be restricted.

The trench 14 has a high aspect ratio greater than or equal to 10 (e.g., about 20) and has the vertical shape. Because the whole surface of the wall and the bottom of the trench is etched substantially uniformly, the trench 14 has no step portion at the wall even in a case where the trench 14 has the high aspect ratio. In addition, corners 14a of the bottom portion and corners 14b of the opening portion are rounded by the isotropic dry etching. Thus, a local concentration of the electric field can be restricted.

When the temperature of the semiconductor substrate 10 is set to be about 100° C., as shown in FIG. 4, the etching rate is substantially uniform in the depth direction. Thus, the trench 14 can be formed vertically.

The above-described formation of the trench 14 and the removal of the damaged layer 22 can be suitably use for forming a trench for isolating elements, a gate electrode having a trench structure such as a metal-oxide semiconductor element (MOS element) and an isolated gate bipolar transistor (IGBT), and a trench in a super junction element having a pn structure in which n-type regions and p-type regions are alternately arranged. For example, the present manufacturing method can be used for forming the trench in the super junction element in a case where a P-type region is formed by epitaxial growth.

As a result, the trench 14 having the high aspect ratio greater than or equal to 10 can be formed by the present manufacturing method. In addition, the damaged layer 22 can be removed from the whole surface of the wall and the bottom of the trench. Thus, a generation of a crystal defect due to the damaged layer 22 can be restricted. Furthermore, no step portion is generated at the wall surface by the isotropic etching. Thus, the local concentration of the electric field can be restricted.

In the manufacturing method shown in FIGS. 8-10, the trench 14 has the vertical shape, as an example. Alternatively, the trench 14 may have a taper shape in which the width of the trench 14 decreases toward at the bottom portion. Alternatively, the trench 14 may have an inverted taper shape in which the width of the trench 14 decreases toward the opening portion. For example, the trench 14 having the taper shape is formed by the RIE, as shown in FIG. 11, and then the damaged layer 22 is removed on the above-described conditions. In the present case, the trench 14 after the removing process can have the taper shape.

As described above, in the manufacturing method shown in FIGS. 8-12, the damaged layer 22 can be removed from the whole surface of the wall and the bottom of the trench, and the shape of the trench 14 after the removing process can reflect the shape of the trench 14 before the removing process.

### Second Embodiment

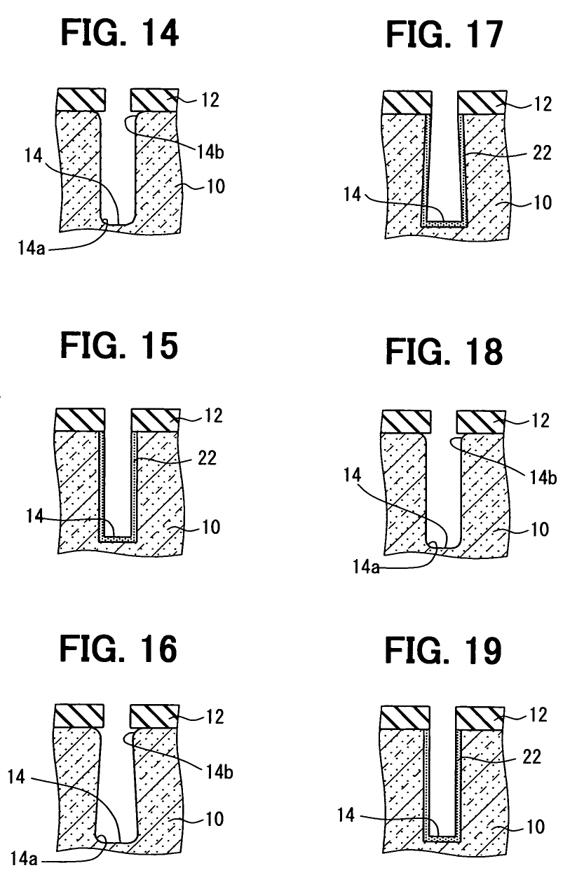

A manufacturing method according to a second embodiment of the invention will be described with reference to FIGS. 13 and 14. In the present embodiment, the temperature of the semiconductor substrate 10 is set to be a predetermined temperature in a range from 20° C. to 90° C.

When the temperature of the semiconductor substrate 10 is less than 90° C., the etching rate increases toward the bottom portion, as shown in FIGS. 3 and 6. For example, when the temperature of the semiconductor substrate 10 is 70° C., the ratio of the etching rate at the bottom portion to the etching rate at the opening portion is in a range from 1.2 to 1.25. Thus, in the trench-forming process, the trench 14 is formed by the RIE so as to have a taper shape in which the width of the trench 14 decreases toward the bottom portion, as shown in FIG. 13. In the removing process, the temperature of the semiconductor substrate 10 is determined so that the trench 14 after the removing process has a vertical shape in which the width of the trench 14 is substantially uniform in the depth direction of the trench 14. Thus, the bottom portion of the trench 14 is etched more than the opening portion, and the trench 14 after the removing process has the vertical shape, as shown in FIG. 14.

When the temperature of the semiconductor substrate 10 is low, the polymerized film 16 is prone to be generated and the bottom portion of the trench 14 is etched more than the opening portion. However, when the temperature is less than 20° C., the generated amount of the polymerized film 16 exceeds the amount of the polymerized film 16 removed by the oxygen radicals even when the oxygen is supplied to the chamber as the second gas. Thus, the damaged layer 22 is difficult to be removed sufficiently. Therefore, the temperature of the semiconductor substrate is set to be the predetermined temperature in a range from 20° C. to 90° C.

In the present manufacturing method, the damaged layer 22 can be removed from the whole surface of the wall and the bottom of the trench and the trench 14 after the removing process can have the vertical shape. Thus, a generation of a crystal defect due to the damaged layer 22 can be restricted. In addition, because no step portion is generated at the trench wall by the isotropic dry etching, the local concentration of the electric field can be restricted.

In the present manufacturing method shown in FIGS. 13 and 14, the trench 14 after the removing process has the vertical shape. Alternatively, the trench 14 may be formed in the trench forming process so as to have a taper shape or a vertical shape, and the trench 14 may be etched in the removing process so as to have an inverted taper shape in which the width of the trench decreases toward the opening portion. For example, when the trench 14 is formed to have a vertical shape in the forming process, as shown in FIG. 15, and the removing process is performed at a predetermined temperature in a range from 20° C. to 90° C., the trench 14 after the removing process has an inverted taper shape as shown in FIG. 16. Also in the present embodiment, the trench 14 having the high aspect ratio greater than or equal to 10 can be formed and the damaged layer 22 can be removed from the whole surface of the wall and the bottom of the trench. In addition, no step portion is generated at the trench wall by the isotropic dry etching.

Furthermore, when the trench 14 is formed to have an inverted taper shape in the trench-forming process, the trench 14 after the removing process has an inverted taper shape having a larger taper angle. Here, the taper angle is an angle from a direction perpendicular to the surface of the semiconductor substrate 10.

### Third Embodiment

A manufacturing method of a semiconductor device according to a third embodiment of the invention will be described with reference to FIGS. 17-18. In the present embodiment, the temperature of the semiconductor substrate 10 is set to be a predetermined temperature in a range from 110° C. to 200° C.

As shown in FIGS. 3, 4, and 7, when the temperature of the semiconductor substrate 10 is greater than 110° C., the etching rate of the trench increases toward the opening portion. For example, when the temperature of the semiconductor substrate 10 is 120° C., as shown in FIG. 4, the ratio of the etching rate at bottom portion to the etching rate at the opening portion is about 0.9. Thus, in the trench-forming process, the trench 14 is formed by the RCE, for example, so as to have an inverted taper shape in which the width of the trench 14 decreases toward the opening portion, as shown in FIG. 17. In the removing process, the temperature of the semiconductor substrate 10 is determined so that the trench 14 after the removing process has a vertical shape in which the width is substantially uniform in the depth direction. Thus, the opening portion of the trench 14 is etched more than the bottom portion, and the trench 14 after the removing process has the vertical shape, as shown in FIG. 18.

When the temperature of the semiconductor substrate 10 is high, the polymerized film 16 is difficult to be generated. Thus, the opening portion is etched more than the bottom portion. However, when the temperature of the semiconductor substrate 10 is greater than 200° C., the polymerized film 16 is generated little. Thus, the most of fluorine radicals 18 are consumed at the opening portion and are difficult to be supplied to the bottom portion. Therefore, the temperature of the semiconductor substrate 10 is set to be a predetermined temperature in a range from 110° C. to 200° C.

In the present manufacturing method, the damaged layer 22 can be removed from the whole surface of the wall and the bottom of the trench and the trench 14 after the removing process can have the vertical shape. Thus, a generation of a crystal defect due to the damaged layer 22 can be restricted. In addition, because no step portion is generated at the trench wall by the isotropic dry etching, the local concentration of the electric field can be restricted.

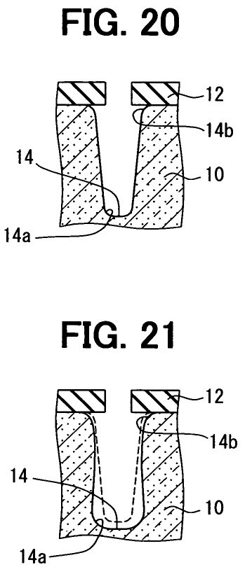

In the present manufacturing method shown in FIGS. 17 and 18, the trench 14 after the removing process has the vertical shape. Alternatively, the trench 14 may be formed in the trench-forming process so as to have an inverted taper shape or a vertical shape, and the trench 14 may be etched in the removing process so as to have a taper shape in which the width decreases toward the bottom portion. For example, when the trench 14 is formed to have the vertical shape in the trench-forming process, as shown in FIG. 19, and the removing process is performed at the predetermined temperature in a range from 110° C. to 200° C., the trench 14 after the removing process has a taper shape as shown in FIG. 20. Also in the present case, the trench 14 having the high aspect ratio greater than or equal to 10 can be formed and the damaged layer 22 can be removed from the whole surface of the wall and the bottom of the trench. In addition, no step portion is generated at the trench wall by the isotropic dry etching.

Furthermore, when the trench 14 is formed to have a taper shape in the trench-forming process, the trench 14 after the removing process has a taper shape having a large taper angle.

### Other Embodiments

Although the present invention has been fully described in connection with the preferred embodiments thereof with reference to the accompanying drawings, it is to be noted that various changes and modifications will become apparent to those skilled in the art.

In the first to third embodiments, the semiconductor substrate 10 is made of silicon. The semiconductor substrate 10 may be made of other material as long as the material includes silicon. For example, the semiconductor substrate 10 may be made of silicon carbide (SiC). When the semiconductor substrate 10 is made of SiC, the amount of oxygen gas as the second gas is required to be increased compared with a case where the semiconductor substrate 10 is made of silicon, for removing carbon in the semiconductor substrate 10. The semiconductor substrate 10 is not limited to be a single-crystal bulk substrate. Alternatively, the semiconductor substrate 10 may be a silicon on insulator (SOI) substrate in which a semiconductor layer is disposed on a supporting substrate through an insulating layer.

In the first to third embodiments, tetrafluoromethane (CF₄) is used as the first gas, as an example. The first gas may be other gas as long as the gas includes at least carbon and fluorine. For example, the first gas may include trifluoromethane (CHF₃), difluorometane (CH₂F₂), or monofluoromethane (CH₃F).

In the first to third embodiments, the temperature of the semiconductor substrate 10 is fixed to a predetermined temperature. Alternatively, the temperature of the semiconductor substrate 10 may be changed in the above-described range. Alternatively, the temperature of the semiconductor substrate 10 may be changed between at least two temperatures selected from a temperature in a range from 90° C. to 110° C., a temperature in a range from 20° C. to 90° C., and a temperature in a range from 110° C. to 200° C. Even when the temperature of the semiconductor substrate 10 is changed, the trench 14 having the high aspect ratio can be formed and the damaged layer 22 can be removed from the whole surface of the wall and the bottom of the trench. Alternatively, the trench 14 may have various shapes. For example, the temperature of the semiconductor substrate 10 may be changed from a temperature in a range from 110° C. to 200° C. to a temperature in a range from 20° C. to 90° C. in the removing process. When a first step of the removing process is performed at the temperature in the range from 110° C. to 200° C., the trench 14 has a taper shape as shown by the broken line in FIG. 21. After a second step of the removing process is performed at the temperature in the range from 20° C. to 90° C., the width at the opening portion and the width at bottom portion become larger than the width at the middle portion, as shown by the solid line in FIG. 21.

In the above-described embodiments, the formation and removal of the polymerized film 16, specifically, the etching rate at each portion in the depth direction is controlled by the temperature of the semiconductor substrate 10. Alternatively, the formation and removal of the polymerized film 16 may be controlled by using the flow ratio of the first gas to the second gas or the pressure in the chamber. For example, when the amount of the first gas increases, the amounts of fluorine radicals 18 and the polymerized film 16 increases, and thereby the etching rate at the bottom portion increases. In contrast, when the amount of the first gas decreases, the amounts of fluorine radicals 18 and the polymerized film 16 decrease, and thereby the etching rate at the opening portion increases. When the pressure in the chamber increases, a molecular density increases and an average molecular speed decreases. Thus, a mean free path decreases and the etching rate at the opening portion increases. In contrast, when the pressure in the chamber decreases, the molecular density decreases and the average molecular speed increases. Thus, the mean free path increases and the etching rate at the bottom portion increases.

Such changes and modifications are to be understood as being within the scope of the present invention as defined by the appended claims.

What is claimed is:

1. A method of manufacturing a semiconductor device, comprising:
forming a trench in a semiconductor substrate by an anisotropic dry etching, wherein the trench has an aspect ratio greater than or equal to 10 and the semiconductor substrate includes silicon; and
removing a damaged layer that is generated in a wall and a bottom of the trench due to the anisotropic dry etching by an isotropic dry etching, wherein the isotropic dry etching is performed with a first gas including carbon and fluorine and a second gas including oxygen, and a temperature of the semiconductor substrate is controlled so that the damaged layer is removed from a whole surface of the wall and the bottom.

2. The method according to claim 1, wherein
the temperature of the semiconductor substrate is set to be in a range from 90° C. to 110° C. in the isotropic dry etching.

3. The method according to claim 2, wherein
the trench is formed by the anisotropic dry etching so as to have a vertical shape in which a width of the trench is substantially uniform in a depth direction of the trench.

4. The method according to claim 2, wherein
the trench is formed by the anisotropic dry etching so as to have a taper shape in which a width of the trench decreases toward a bottom portion of the trench.

5. The method according to claim 2, wherein
the trench is formed by the anisotropic dry etching so as to have an inverted taper shape in which a width of the trench decreases toward an opening portion of the trench.

6. The method according to claim 1, wherein
the temperature of the semiconductor substrate is set to be in a range from 20° C. to 90° C. in the isotropic dry etching.

7. The method according to claim 6, wherein:
the trench is formed by the anisotropic dry etching so as to have a taper shape in which a width of the trench decreases toward a bottom portion of the trench; and
the trench is etched by the isotropic dry etching so as to have a vertical shape in which the width of the trench is substantially uniform in a depth direction of the trench.

8. The method according to claim 6, wherein:
the trench is formed by the anisotropic dry etching so as to have a taper shape in which a width of the trench decreases toward a bottom portion of the trench; and
the trench is etched by the isotropic dry etching so as to have an inverted taper shape in which the width of the trench decreases toward an opening portion of the trench.

9. The method according to claim 6, wherein:
the trench is formed by the anisotropic dry etching so as to have a vertical shape in which a width of the trench is substantially uniform in a depth direction of the trench; and
the trench is etched by the isotropic dry etching so as to have an inverted taper shape in which the width of the trench decreases toward an opening portion of the trench.

10. The method according to claim 1, wherein:
the temperature of the semiconductor substrate is set to be in a range from 110° C. to 200° C. in the isotropic dry etching.

11. The method according to claim 10, wherein:
the trench is formed by the anisotropic dry etching so as to have an inverted taper shape in which a width of the trench decreases toward an opening portion of the trench; and
the trench is etched by the isotropic dry etching so as to have a vertical shape in which the width of the trench is substantially uniform in a depth direction of the trench.

12. The method according to claim 10, wherein:
the trench is formed by the anisotropic dry etching so as to have an inverted taper shape in which a width of the trench decreases toward an opening portion of the trench; and
the trench is etched by the isotropic dry etching so as to have a taper shape in which the width of the trench decreases toward a bottom portion of the trench.

13. The method according to claim 10, wherein:
the trench is formed by the anisotropic dry etching so as to have a vertical shape in which a width of the trench is substantially uniform in a depth direction of the trench; and
the trench is etched by the isotropic dry etching so as to have a taper shape in which the width of the trench decreases toward a bottom portion of the trench.

14. The method according to claim 1, wherein:
the temperature of the semiconductor substrate is changed between at least two temperatures that are selected from a first temperature in a range from 20° C. to 90° C., a second temperature in a range from 90° C. to 110° C., and a third temperature in a range from 110° C. to 200° C. during the isotropic dry etching is performed.
